(19) United States
(12) Patent Application Publication
(10) Pub. No.: US 2021/0288284 A1
(43) Pub. Date: Sep. 16, 2021

(54) OLED DISPLAY PANEL AND MANUFACTURING METHOD THEREOF

(71) Applicant: SeeYA Optronics Co., Ltd., Shanghai (CN)

(72) Inventor: Zhongshou HUANG, Shanghai (CN)

(21) Appl. No.: 17/332,252

(22) Filed: May 27, 2021

(30) Foreign Application Priority Data
Nov. 26, 2020 (CN) 202011342810.7

(51) Int. Cl. H01L 51/52; H01L 27/32; H01L 51/00; H01L 51/56

(52) U.S. Cl. CPC H01L 51/5225; H01L 27/3246; H01L 2227/323; H01L 51/0021; H01L 51/56; H01L 51/001

(57) ABSTRACT

An OLED display panel and a manufacturing method therefor are disclosed. The display panel includes: a substrate, a first electrode, a pixel definition layer, a plurality of openings of the pixel definition layer, fence structures laid in the openings, a light-emitting functional layer and a second electrode. An evaporation process is conducted to form a surface topology that the second electrode thickness on the side wall of the fences and on the bottom of the trenches between the fences are thinner than an nominal thickness of the second electrode on the top of the fences. The present disclosure can effectively increase a light output from the light-emitting functional layer while keep the overall resistance of the second electrode under controlled.

### CROSS-REFERENCE TO RELATED APPLICATIONS

The present application claims priority to Chinese Patent Application No. 202011342810.7, filed on Nov. 26, 2020, the content of which is incorporated herein by reference in its entirety.

### TECHNICAL FIELD

The present disclosure relates to the field of display technology, and in particular, to an OLED display panel, a method for manufacturing the OLED display panel.

### BACKGROUND

With the development of Organic Light Emitting Diode (OLED) display technology and expansion of a large-scale manufacturing industry thereof, OLED displays not only have become a mainstream of mobile displays, but also occupy a considerable market share of medium-sized PC monitors and even large-sized TV displays.

However, as OLED display technology gradually penetrates into some special display application fields, such as augment reality (AR) and virtual reality (VR) display fields, various restrictions of a conventional device structure on display performances have become more and more obvious. Taking the micro display in AR and VR glasses as an example, features including lighter, thinner and smaller display device, and at the same time higher image spatial resolution, lower power consumption and higher brightness, are becoming fundamental requirements. However, the miniaturization in geometric factors and pursing higher display performance inevitably results in tricky challenges to deal with apparently conflict requirements in display designs and fabrications. The display performances, such as brightness, color gamut and power consumption will be significantly degraded, unless new device structures and manufacturing method thereof are developed and implemented.

### SUMMARY

In view of this, the embodiments of the present disclosure provide an OLED display panel and a related manufacturing method, which can effectively increase a light output from the display panel by reducing thickness of a cathode metal layer locally while keeping overall sheet resistance of the cathode metal layer under controlled.

In a first aspect, an embodiment of the present disclosure provides an OLED display panel, including a substrate, and a light-emitting device disposed on the substrate. The light-emitting device includes: a first electrode; a PDL located on a side of the first electrode facing away from the substrate, the PDL including a plurality of openings which expose a part of the first electrode; fence structures located in the plurality of openings and facing away from the substrate; a light-emitting functional layer provided on a side of the PDL, the plurality of openings, and the fence structures, facing away from the substrate; and a second electrode overlapped on the light-emitting functional layer. Each of the fence structures includes fences, and trenches which are spaces are formed between the fences and the PDL, and between two adjacent fences. The second electrode has a thickness distribution with a thicker layer on a top of each of the fences and a thinner layer on a bottom of the trenches and on a side wall of the fences.

In a second aspect, an embodiment of the present disclosure provides a manufacturing method for the OLED display panel of the first aspect, the manufacturing method including: disposing the substrate which is overlaid with the first electrode, the PDL and the fence structures on a supporting stage inside a vapor deposition chamber; providing a crucible or a sputtering target containing a raw material for forming the light-emitting functional layer in the vapor deposition chamber, and forming the light-emitting functional layer on the substrate by heating the crucible or plasma bombarding the sputtering target under a first chamber gas pressure; and providing a crucible or a sputtering target containing a raw material for forming the second electrode in the vapor deposition chamber, and forming the second electrode on the substrate by heating the crucible or plasma bombarding the sputtering target under a second chamber gas pressure, wherein the first chamber gas pressure is higher than the second chamber gas pressure.

The OLED display panel and the manufacturing method for manufacturing the OLED display panel provided by the present disclosure will have the following benefits.

In the embodiments of the present disclosure, the light output from the bottom of the trenches and from the side wall of the fences are increased, attributed to an absorption reduction or alternatively a thickness reduction of the second electrode (cathode of the OLED display panel) at these locations. In addition, as the fence-trench surface topology is scaled down to nanometer scale, the light output of the light emitting functional layer may increase substantially, attributed to characteristics of nanometer surface pattern.

As increasing display resolution, an effective illumination area in each OLED pixel will decrease. To tackle this problem, one of conventional approaches is thinning the whole second electrode layer to maximize transmission of the second electrode layer. However this will inevitably result in a consequence “voltage drop” along OLED current paths. In the embodiments of the present disclosure, layer thinning occurs only in each pixel of a display and only on the side walls of the fences and on the bottoms of the trenches. Therefore, sheet resistance of the second electrode, which is dominated by interconnections between pixels of the display, is essentially not affected and will be kept unchanged or slightly increased. Voltage drop is then minimized as pixel dimension scaling down or display resolution increasing.

### BRIEF DESCRIPTION OF DRAWINGS

In order to clearly illustrate technical solutions in embodiments of the present disclosure, the accompanying drawings used in the embodiments are briefly described below. It should be noted that the drawings described are merely part of the embodiments of the present disclosure, and those skilled in the art can make extensions and modifications from the principles and concepts disclosed in the embodiments of the present disclosure to conceive other similar structures, and all these structures conceived based on the principles and concepts disclosed in the embodiments of the present disclosure shall fall into the protection scope of the present disclosure.

FIG. 1 illustrates a cross-sectional view in an X-Z plane of a single subpixel in a display panel in the related art;

FIG. 2 illustrates a cross-sectional view of two adjacent subpixels in an X-Z plane of an OLED display panel according to an embodiment of the present disclosure;

FIG. 3 illustrates a top view of a fence structure in a single subpixel according to an embodiment of the present disclosure;

FIG. 4 illustrates a cross-sectional view along line A1-A2 in FIG. 3;

FIG. 5 illustrates a top view of a fence structure in a single opening according to another embodiment of the present disclosure;

FIG. 6 illustrates a dimension of a fence structure according to an embodiment of the present disclosure;

FIG. 7 illustrates a top view of a fence structure in a single subpixel according to still another embodiment of the present disclosure;

FIG. 8 illustrates a top view of a fence structure in a single subpixel according to yet another embodiment of the present disclosure;

FIG. 9 illustrates a top view of a fence structure in a single subpixel according to yet another embodiment of the present disclosure;

FIG. 10 illustrates a top view of a fence structure in a single subpixel according to yet another embodiment of the present disclosure;

FIG. 11 illustrates a top view of a fence structure in a single subpixel according to yet another embodiment of the present disclosure;

FIG. 12 illustrates a schematic diagram of a structure of an encapsulation protection layer according to an embodiment of the present disclosure;

FIG. 13 illustrates a schematic diagram of a fence structure according to an embodiment of the present disclosure;

FIG. 14 illustrates a flowchart of a manufacturing method according to an embodiment of the present disclosure;

FIG. 15 illustrates a schematic diagram of a vapor deposition process for a second electrode according to an embodiment of the present disclosure;

FIG. 16 illustrates a normalized thickness distribution of a second electrode on a bottom of a trench according to an embodiment of the present disclosure;

FIG. 17 illustrates a process flow of an OLED display panel according to an embodiment of the present disclosure; and

FIG. 18 illustrates a structure of an OLED display device according to an embodiment of the present disclosure.

### DESCRIPTION OF EMBODIMENTS

The technical solutions in the embodiments of the present disclosure are described below with reference to the accompanying drawings. It should be noted that the described embodiments are merely exemplary embodiments of the present disclosure, which shall not be interpreted as limiting the present disclosure. All other embodiments obtained by those skilled in the art based on the concepts and methods disclosed in the present disclosure shall fall within the protection scope of the present disclosure.

The terms used in the embodiments of the present disclosure are merely for the purpose of describing particular embodiments but not intended to limit the present disclosure. Unless otherwise noted in the context, the singular form expressions prefixed with “a”, “an”, “the” and “said” used in the embodiments and appended claims of the present disclosure are also intended to represent plural form expressions thereof.

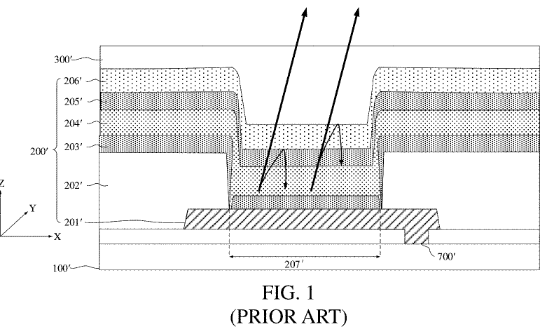

A micro display used in an existing AR or VR glass is taken as an example for illustration below. FIG. 1 illustrates a cross-sectional view in an X-Z plane of a single subpixel in a display panel. As shown in FIG. 1, different from a structure design using glass as a substrate of a medium-sized or large-sized display, a display panel of the micro display usually uses a silicon wafer as the substrate 100′, and structures such as pixel circuits, row scan circuits, and signal driving circuits are integrated onto this silicon wafer, utilizing the advantages of a large-scale integrated circuit. A light-emitting device 200′ and a first planarization layer 300′ are sequentially stacked up on the substrate 100′. The light-emitting device 200′ includes an anode 201′, a pixel definition layer (PDL hereinafter) 202′, a hole injection and transport layer 203′, a light-emitting layer 204′, an electron injection and transport layer 205′, and a cathode 206′ that are stacked up in sequence. Via a through hole 700′, the anode 201′ is electrically connected to a pixel circuit in the substrate 100′. The PDL 202′ has an opening 207′ that defines an effective light output region of the subpixel. The hole injection and transport layer 203′, the light-emitting layer 204′, the electron injection and transport layer 205′, and the cathode 206′ are sequentially deposited on a part of the anode 201′ which is exposed in the opening 207′. A large slope angle even greater than 90° at the side wall of the opening 207′ is purposely produced for the PDL so that the hole injection and transport layer 203′ is substantially discontinuous at the side walls.

Based on the structure described above, when the display panel is operated, light emitted from the light-emitting layer 204′ must pass through the multiple layers before reaching free space, where the multiple layers are stacked on the light-emitting layer 204′ and may have different refractive indexes. The light reflection will occur where ever two adjacent layers have different refractive indexes, or will be attenuated due to absorption in each layer, resulting in a negligible loss, thereby adversely affecting light extraction capability of the display panel.

In the prior art, in order to improve an electron injection efficiency, the cathode layer 206′ is usually formed by a metal material with stable chemical properties and a small work function. A silver alloy or an aluminum alloy is commonly used in the related art, e.g., a Mg:Ag (10:1) alloy electrode with a work function of 3.7 eV, or a Li:Al (0.6% Li) alloy electrode with a work function of 3.2 eV.

The cathode layer formed by the silver alloy or the aluminum alloy is usually an opaque metal film unless the layer thickness is thinner than or equal to 50 nm. Taking the silver metal as an example, the imaginary part of the complex refractive index of silver metal, i.e., the extinction coefficient k is approximately 3.6. When a yellow-green light with a wavelength λ of 550 nm is incident onto the silver metal, an absorption coefficient α of the silver metal for the yellow-green light is approximately 8.22×10⁵ cm⁻¹ according to a relationship between the absorption coefficient α and the extinction coefficient k that α=4πk/λ. For an 80 nm thick silver metal, approximately 99% of the incident light will be absorbed, the light loss will be reduced to 91% as the silver metal is reduced to 30 nm.

On the other hand, a real part of the complex refractive index of the silver metal, i.e., its refractive index, is approximately 0.2. Generally, in the OLED display panel, the light-emitting layer 204′ and the electron injection and transport layer 205′ have a similar refractive index around 1.5, and the first planarization layer 300′ has a refractive index around 1.45. As illustrated in FIG. 1, the large discrepancy of the refractive index between the silver metal cathode and the layers on its two sides, will cause significant reflection and result in only 12% or less OLED light that can be extracted from the light-emitting layer 204′.

According to the physical properties of a thin metal film, however, when the thickness of the thin metal film is reduced to a nanometer scale, for instance 20 nm, a physical mechanism of resonance absorption and reflection in the metal lattice related to the wavelength of light is no longer applicable, and the light transmittance of the film is dominated by various nanometer effects in both the reflection and the absorption. According to the research, for a silver metal layer with a thickness less than 20 nm, the transmittance of visible light may increase 40% or more of the value estimated based on a conventional geometric optics.

However, if the cathode layer 206′ is simply formed by an extremely thin metal film, its sheet resistance will increase significantly. For example, a 20 nm thick silver metal film has a sheet resistance approximately 1Ω per square. Moreover, other factors such as surface oxidation of the cathode layer induced by an oxide coverage on the cathode layer, or uneven surface topology on which the cathode layer is laid on, tend to further reduce the average thickness of the silver metal, and then the sheet resistance of the cathode layer 206′ may increase to 2 to 4Ω per square or even larger.

For an OLED display array with a certain area, the cathode layer is required to bear a larger transient current in order to maintain voltage difference between anode and cathode of millions of OLEDs in the OLED display array. If the sheet resistance of the cathode layer 206′ is too high, OLED current on the cathode layer will not be quickly dissipated, and result in non-uniform voltage drop across the entire OLED display array. As a result, display performance including uniformity of brightness and color gamut decreases. Moreover, the voltage drop in the cathode layer is equivalent to a reduction of OLED bias voltage, and therefore results in a reduction of the display brightness. This phenomenon may become more obvious especially when an image is refreshed from a previous one as brightness distribution on the OLED display changes. It is generally more difficult to correct an image shadow and color deviation caused by the two-dimensional and non-uniform voltage drop on the display image.

It is understood from the above analysis that the light extraction capability of the OLED display panel cannot be improved simply by thinning the entire cathode layer 206′ without sacrificing other image performance that are related to the sheet resistance of the cathode layer.

It is therefore the primary object of present disclosure to provide a technical solution to improve the light extraction capability of the OLED display panel without sacrificing image performance related to the sheet resistance of the cathode layer.

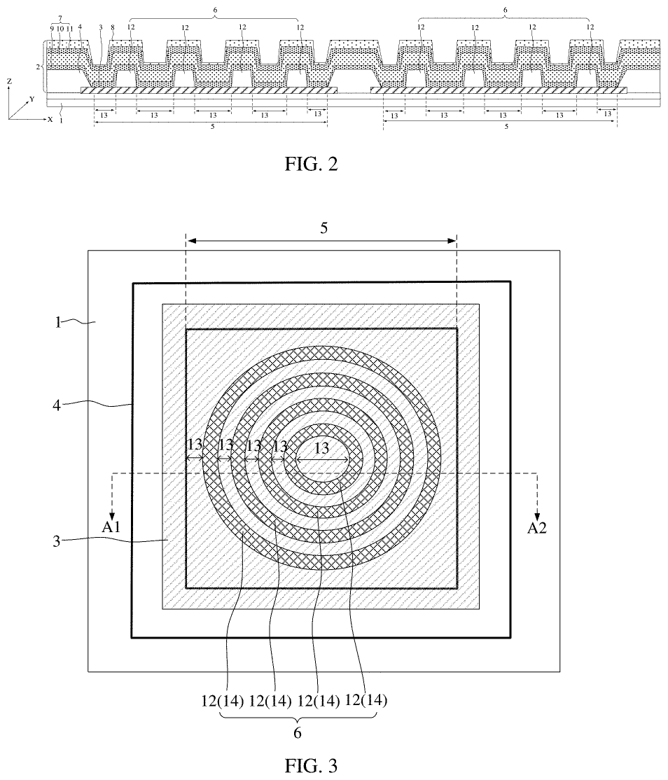

An embodiment of the present disclosure is illustrated in FIG. 2, which can be applied to a micro OLED display in the AR and VR fields. FIG. 2 illustrates a cross-sectional view of two adjacent subpixels in an X-Z plane of an OLED display panel according to the embodiment. The OLED display panel includes a substrate 1, which may be a silicon chip integrated with a pixel circuit, a row scanning circuit, and a signal driving circuit.

A light-emitting device 2 is arranged on the substrate 1, and the light-emitting device 2 includes: a first electrode 3, i.e., the anode described above, the first electrode 3 being electrically connected to the pixel circuit (not shown in the figure) integrated in the substrate 1 to receive an OLED driving current; a PDL 4 covering on the first electrode 3, the PDL 4 having a plurality of openings 5 for exposing a part of the first electrode 3 and therefore defining actual light output regions of the subpixels; a fence structures 6 located in the plurality of openings 5; a light-emitting functional layer 7 disposed on the PDL 4, the openings 5 and the fence structures 6; and a second electrode 8, i.e., the aforementioned cathode layer overlapped on the light-emitting functional layer 7. As shown in FIG. 2, the light-emitting functional layer 7 may include a hole injection and transport layer 9, a light-emitting layer 10, and an electron injection and transport layer 11 stacked on the anode. The injection and transport layer 9 may include two layers, i.e., a hole injection layer and a hole transport layer; and the electron injection and transport layer 11 may include two layers, i.e., an electron injection layer and an electron transport layer. The light-emitting functional layer 7 may also include a plurality of layers, which will not be further described hereinafter.

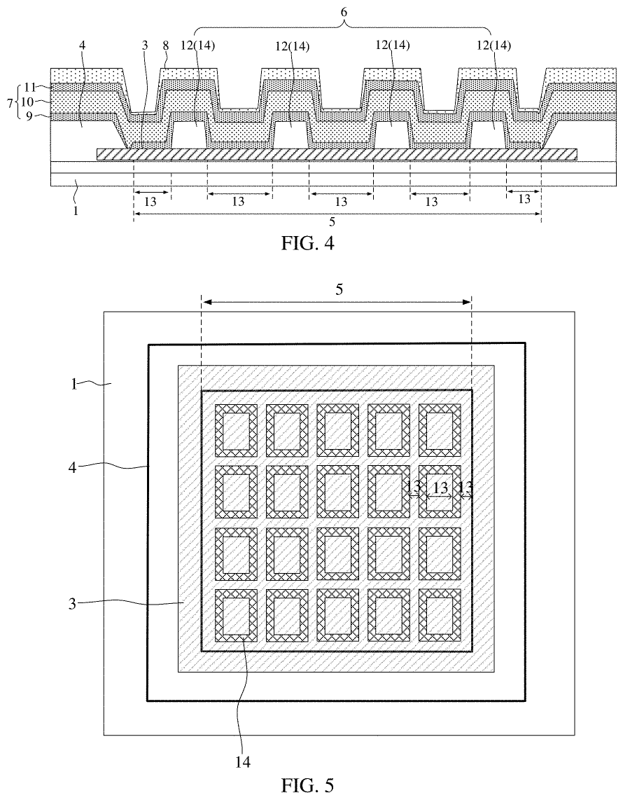

FIG. 3 illustrates a top view of the fence structure in a single subpixel according to an embodiment of the present disclosure. FIG. 4 illustrates a cross-sectional view along line A1-A2 in FIG. 3. As shown in FIG. 3 and FIG. 4, the fence structure 6 includes a plurality of fences 12, and a plurality of trenches 13 which are space between the PDL 4 and plurality of fences 12, or between two adjacent fences 12. The second electrode 8 has a thickness distribution with a thicker layer on a top of each of the fences 12 and a thinner layer on a bottom of the trenches 13 and on a side wall of the fences 12.

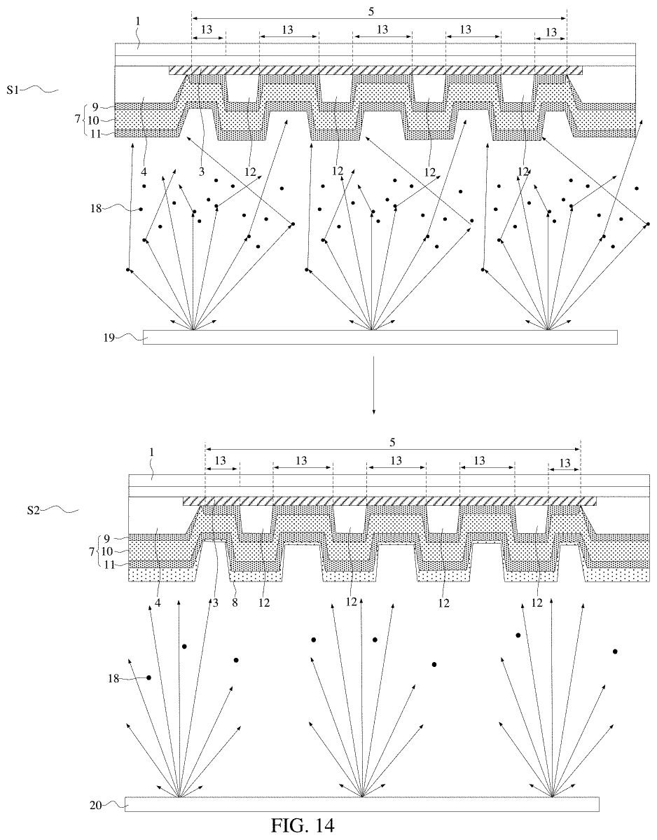

Now referring to FIG. 14, after preparation of the first electrode 3, the fence structures 6 and the PDL 4 are formed on the substrate 1. The subsequent layers of the OLED, i.e., the hole injection and transport layer 9, the light-emitting layer 10, the electron injection and transport layer 11 and the second electrode 8 are sequentially deposited by vapor deposition process under different ambient pressure according to an embodiment of the present disclosure.

More specifically, crucibles containing a raw materials of the hole injection and transport layer 9, the light-emitting layer 10, the electron injection and transport layer 11, respectively, are heated in an inert gas environment inside of a vapor evaporation chamber. Organic molecules evaporated from the crucibles collide with the inert gas molecules multiple times and tend to land on the array substrate more evenly and in all angles. As results, the organic films are uniformly attached to every surfaces and corners of the fences 12 and the trenches 13. A thickness differences among the deposited organic films on the top and the side wall of the fences 12, and on the bottom of the trenches 13, decrease with increase of the inert gas pressure till under a measurable limit.

When forming the second electrode 8, i.e. the said cathode layer, the pressure of the inert gas inside the vapor deposition chamber is greatly reduced to a level that the metal atoms or alloy molecules evaporated from the crucible or other source are straightly landed onto the substrate 1 without being diffused by collision with gas molecules. During the deposition process, the top of the fence 12 is not shielded by any other structure, receiving metal materials from all angles of a semispherical space, and then having the thickest cathode layer, while the side wall of the fence 12 and the bottom of the trench 13 are partially shielded by adjacent fences or PDL, receiving less metal materials and then having a thinner cathode layer.

Benefit from the thinner cathode layer on the side wall of the fences and on the bottom of the trenches, more light will be extracted there. In addition, as the thickness of the cathode layer decreases to nanometer scale, as briefly described, unique nano film effects will emerge and play that the light transmittance increases substantially.

Contrary to the approach in prior art, where the thickness of the entire cathode layer is reduced for better light output, the embodiment of the present disclosure provides an unique structure that the thickness of the cathode layer on PDL and top of the fences, which are the main paths of the cathode current, are kept same as the conventional thickness. Therefore voltage drop on the entire cathode is minimized or negligible, and thus the OLED display performance such as brightness uniformity and color gamut of the display are essentially not affected.

It should be noted that, in the embodiment of the present disclosure, although the side walls of the fences 12 and the bottoms of the trenches 13 have a thinner anode layer, OLED current can drift laterally to the top of the fence or PDL where thicker metal layers facilitate the main cathode current path. The OLED film on the side wall of the fences and on the bottom of the trench still have adequate bias voltage and therefore emit light as usual.

Now referring to FIG. 4, the fence structure 6 includes a plurality of first fences 14, and each first fence 14 is a ring-shaped fence around a center of the opening, in a plane parallel to the substrate. The plurality of first fences 14 are arranged in a concentric nesting manner in a plane parallel to the substrate 1. An alternative arrangement as another embodiment of the present disclosure, as illustrated in FIG. 5 with its top view, includes a plurality of first fences 14 arranged into a matrix in a plane parallel to the substrate 1. No matter the first fences 14 are nested within each other, or arranged into a matrix, in general, the length of the fence 12 is substantially larger than its thickness and height. Alternatively in some other embodiments, each first fence 14 may be a line-shaped fence disposed on a plane parallel to the substrate.

It should be noted that the shapes of the first fence 14 shown in FIG. 3 and FIG. 5 are merely exemplary embodiments for better understanding a structural concept of the present disclosure, and both the square ring and the circular ring can be arranged into a matrix or nested within each other.

One benefit of using the described arrangements wherein the ring-shaped fences are approximately uniformly distributed within the opening, is to average light transmittance which varies from the bottom of the trench to the side wall of the fence and to the top of the fence. This benefit may contribute to a better uniform brightness in the OLED display array.

In order to further improve the uniformity of the light transmittance within the opening 5, in an alternative embodiment, the first fences are substantially equal-spaced from each other and all the trenches have a similar width accordingly.

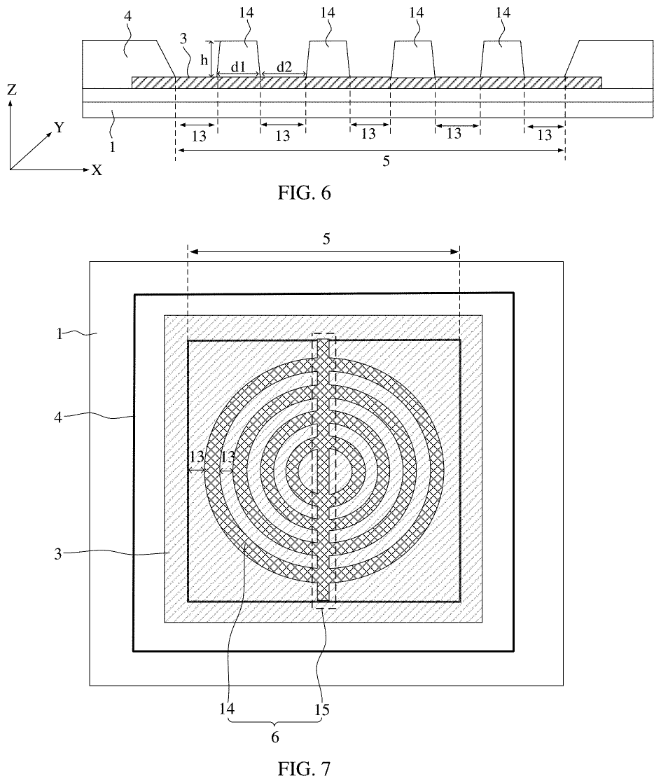

Now referring to FIG. 6, where h denotes the height of the first fence 14, d1 denotes an average fence thickness, in some embodiments, the fence height to the fence thickness ratio, i.e. h/d1 is kept within a range from 0.5 to 2.0, or 0.5≤h/d1≤2.

Still referring to FIG. 6, wherein d2 denotes the width of the trench 13, which approximately equal to a spatial distance between two adjacent first fences 14, in some embodiments, a ratio d1/(d1+d2) is kept within a range from 0.3 to 0.75, or expressed by 0.3≤d1/(d1+d2)≤0.75.

In some embodiments wherein the fences and the trenches are alternatively and periodically repeated on the X-Z plane, the ratio d1/(d1+d2) can be referred as a duty-cycle of an up-and-down topology of the fence structure.

Within the given duty-cycle range, an appropriate duty-cycle should be selected based on lithography process capability as well, aiming high manufacture yield, performance uniformity and reliability of the OLED display panel.

Another parameter of the fence structure which can be extracted from FIG. 6, is a trench depth to the trench width ratio. The trench depth, as suggested in FIG. 6, has an equal value as the fence height h. In another embodiment of the present disclosure, the trench depth to the trench width ratio is kept in a range from 0.5 to 2.0, or expressed as 0.5≤h/d2≤2. When the depth to width ratio of the trench is higher than 2.0, a large portion of the LED light emitted from the bottom of the trench or from the side wall of the fences may not be able to escape from the trench. When the depth to width ratio of the trench is lower than 0.5, the thickness of the cathode layer on the bottom of the trench may still be too thick for ideal optical transmittance.

In order to produce an ideal OLED display panel according the present disclosure, not only the geometric dimensions of the fence and the trench should meet these ranges or criteria, but also the evaporation chamber setup and inner gas pressure should be optimized for the fence and the trench profiles.

In another embodiment according to the present disclosure, the geometric dimensions of the fence structure including h, d1 and d2 are scaled down to a nanometer range, e.g., approximately 100 nm or even less. In this case, a unique physical effect attributed to nanostructure becomes important, which significantly reduces the optical reflection and diffraction based on classical Fresnel optics theory. Therefore, this embodiment using a fence structure in nanometer dimension can gain more OLED light output from the OLED display panel.

It should be noted that since a silicon wafer can be used as the substrate in the present disclosure, nanometer IC processing technology implemented in a mature semiconductor chip manufacturer can sufficiently meet such fine patterning requirements given above. In another words, it is completely feasible in real process that the geometric dimensions of the fence structures including h, d1 and d2 are made less than 100 nm.

FIG. 7 and FIG. 8 illustrate top views of fence structure of two embodiments of the present disclosure respectively, wherein the fence structure 6 further includes a second fence 15 which connects the plurality of first fences 14 and the PDL 4. Therefore, the second electrode layer in one subpixel keeps solid continuity on a relatively flat surface from the first fences to the second fences and to the PDL, and the second electrode layers in every subpixel are pieced together becoming one cathode layer of the OLED and providing one bias voltage every subpixel in the OLED.

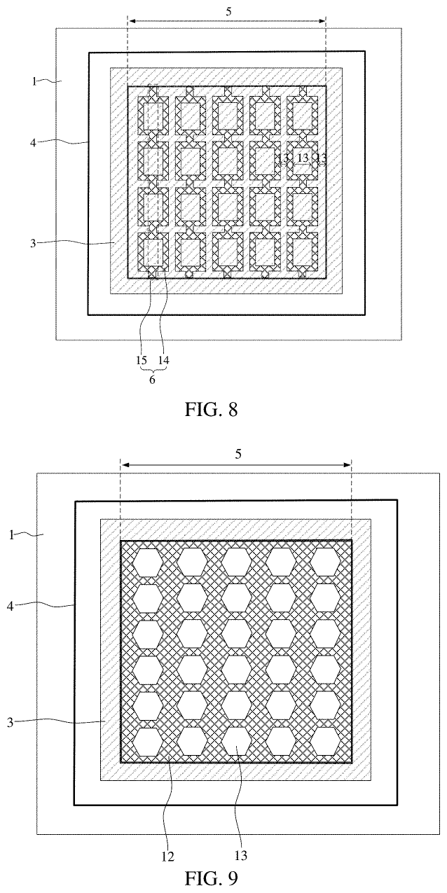

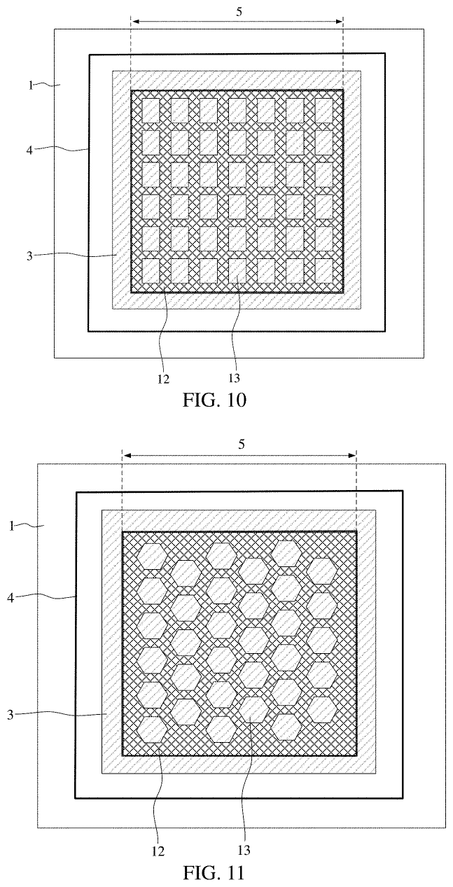

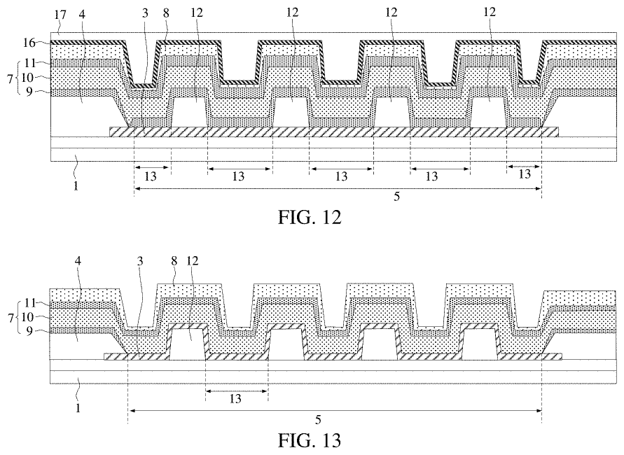

FIG. 9 illustrates a top view of a fence structure 6 in a subpixel according to an embodiment of the present disclosure, wherein a plurality of trenches 13 are arranged into a matrix, and each of them is equivalently a polygonal shaped hole, e.g., a regular hexagonal shaped hole, or a rectangular shaped hole as shown in FIG. 10, in a plane parallel to the substrate 1 and inside the opening 5. The fence 12 and the trench 13 in FIG. 9 and FIG. 10, can be created on a film by simply etching a plurality of polygonal holes.

As one variety of the embodiment illustrated in FIG. 9, FIG. 11 illustrates a top view of another embodiment of the present disclosure, wherein the plurality of hexagonal shaped holes are arranged in a honeycomb structure. With the honeycomb structure, the space of the opening 5 can be utilized in high efficiency, so that more OLED area is covered by thinner cathode layer and resulting in higher light transmittance.

In other embodiments of the present disclosure, the trench 13 may have various shapes, such as a circle, or an ellipse, or a rhombus, or an octagon, all of which shall fall into the scope of the present disclosure and will not be repeated hereinafter.

Now referring back to FIG. 4, because the fence structure 6 is located between the first electrode 3 and the light-emitting functional layer 7, the hole injection and transport layer 9 on the top of the fence 12 cannot directly contact the first electrode 3. Fortunately, since holes can diffuse laterally in the hole injection and transport layer 9, the potential of the hole injection and transport layer 9 can be kept substantially same as the potential of the first electrode 3, even the fence structure 6 is formed by an insulation material. Therefore, the light-emitting devices on the side wall of the fence 12 and on the top of the fence 12 can emit light normally.

Now considering the fence height respect to the PDL height, in some embodiments, the fence height is lower than the PDL height, whereby the PDL 4 can function as a partition wall between adjacent subpixels and a support means for upper layer such as color filter and cover glass. For the sake of simplicity, the fence 12 and the PDL 4 may be formed simultaneously by a same material in one coating process and one photolithography process.

FIG. 13 illustrates a schematic diagram of the fence structure 6 according to an alternative embodiment of the present disclosure, wherein the fence structure 6 is located between the first electrode 3 and the substrate 1. In this case, the hole injection and transport layer 9 directly contacts the first electrode 3 and obtains substantially a same potential from the first electrode 3 in the opening 5. Comparing to the structure shown in FIG. 4, where maintaining the potential of the hole injection and transport layer 9 solely relies on lateral charge diffusion, the structure shown in FIG. 13 provides an uniform OLED bias voltage within each subpixel and therefore improved luminous intensity.

In an embodiment, the fence structure 6 is formed on the first electrode 3 by an insulation material, either entirely by an inorganic materials such as silicon nitride, or by an organic material sealed by silicon oxide or silicon nitride film for blocking moisture. No matter the first electrode is made from a metal or a metal oxide, etch selectivity between the first electrode and the fence structure formed by the insulation material is adequate for patterning the fence structure on the first electrode 3.

In an embodiment, the fence structure 6 may also be made from a conductive or semiconductive materials, including metal, metal oxide, silicon. OLED bias voltage provided by the first electrode 3 can be readily applied to the light-emitting layer through the conductive or semiconductive fence structure 6.

FIG. 14 illustrates a manufacturing method in terms of a flowchart according to an embodiment of the present disclosure. The flowchart includes following two steps S1 and S2.

In the step S1, the substrate 1 which is overlaid with the first electrode, the PDL and the fence structures is disposed on a supporting stage in a vapor deposition chamber; an evaporation source 19 such as a crucible or a sputtering target material, containing a raw material for forming the light-emitting functional layer, is mounted inside the vapor deposition chamber; and the raw materials are deposited in a sequence onto the substrate 1 by heating the crucible or plasma bombarding the sputtering target under a first chamber gas pressure.

Specifically, inert gas 18 is introduced into the vapor deposition chamber, the substrate 1 faces downwards, the evaporation source 19 is located under the substrate 1 and faces upwards so that the atoms or molecules of the raw materials emitted from the evaporation source 19 fly toward the substrate 1; the atoms or molecules of the raw materials may collide with the atoms of the inert gas during the flying journey, and change their directions as illustrated by arrows in FIG. 14; and the atoms or molecules of the raw material finally land on the substrate 1 in various angles after sufficient colliding and diffusion.

In the step S2, an evaporation source 20 (e.g., crucible or sputtering target material) containing a raw material for forming the second electrode is then heated or plasma bombarded under a second chamber gas pressure which is set to be higher than the first chamber gas pressure.

Specifically, when the gas pressure inside the deposition chamber is reduced, the atoms or molecules of the second electrode tend to collide less with gas molecules during their flying journey toward the substrate 1. With less collision with gas molecules, those atoms or molecules flying in larger angle from evaporation source have substantially large chances to be blocked by the fences, based on the shadowing effect of the fences. As results, the second electrode on the side walls of the fences 12 becomes thinner than the second electrode on the top of the fences, and so does the second electrode on the bottom of the trenches 13.

Benefiting from the thickness distribution of the second electrode described herein, more OLED light will pass through the second electrode from the sidewall of the fences and from the bottom of the trenches 13. Overall sheet resistance of the second electrode, which is substantially dominated by thicker conductive layer on the top of the fences and on the top of the PDL, remain substantially unchanged or slightly increase without hindering the OLED operation or reducing overall performance.

Further, the supporting stage may be rotated at a constant speed and in a rotating surface parallel to the substrate, in order to improve the uniformity of the thickness of the deposited film, during the film forming process of the second electrode 8.

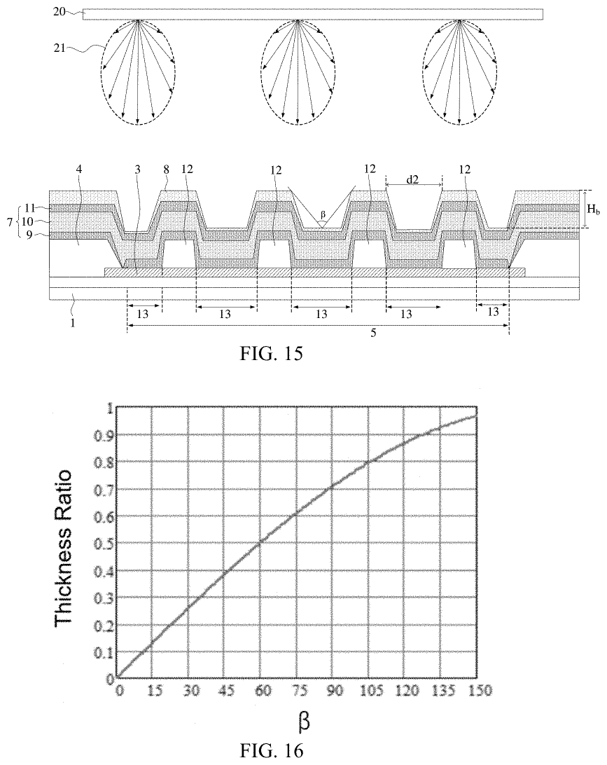

FIG. 15 illustrates a schematic diagram of a vapor deposition process for a second electrode according to an embodiment of the present disclosure. As shown in FIG. 15, in the vapor deposition process for the second electrode 8, the evaporation source 20 containing the second electrode raw material is a planar evaporation source parallel to the substrate 1, and each point on the planar evaporation source represents a point evaporation source 21. The number of atoms or molecules of the material emitted from each point evaporation source 21 follow a cosine distribution law within a 180-degree semispherical space. FIG. 16 plots a normalized thickness distribution of the second electrode on the bottom of the trench. The horizontal axis in FIG. 16 represents an opening angle β in FIG. 15, viewing from a center of a bottom of the trench 13. The value of β is determined by the equation tan(β/2)=d2/(2H_{b}), where H_{b} denotes a step height of the second electrode 8 respect to the bottom of the trench 13, and d2 denotes a trench width of the trench 13. The normalized thickness distribution, as shown on the vertical axis in FIG. 16 represents a thickness ratio between the second electrode on the bottom of the trench 13 and the second electrode on the top of the fence 12. The normalized thickness of the second electrode 8 on the bottoms of the trenches 13 is approximately 37% when the opening angle β is 45 degrees, and it increases to 45% when the opening angle β increases to 53 degree.

In some embodiments, the opening angle β is made within a range of 30°≤β≤90°, such that the second electrode 8 is significantly thinner on the bottoms of the trenches than the second electrode 8 on the tops of the fences 12. When the thickness of the second electrode 8 on the bottoms of the trenches 13 is significantly smaller than a wavelength of light emitted from the light-emitting layer 10, e.g., smaller than 50 nm, optical characteristics arising from a nanometer scale effect will enhance the light transmittance.

During the film deposition, some molecules or atoms flying from the evaporation source are bounced back or scattered on their landing surface and change their flying directions. As a result, the metal thickness on the bottoms of the trenches 13 is slightly increased from the value predicted from the theoretic model plotted in FIG. 16. Nevertheless, the second electrode on the bottoms of the trenches 13 is still substantially thinner than the second electrode deposited on the tops of the fences 12.

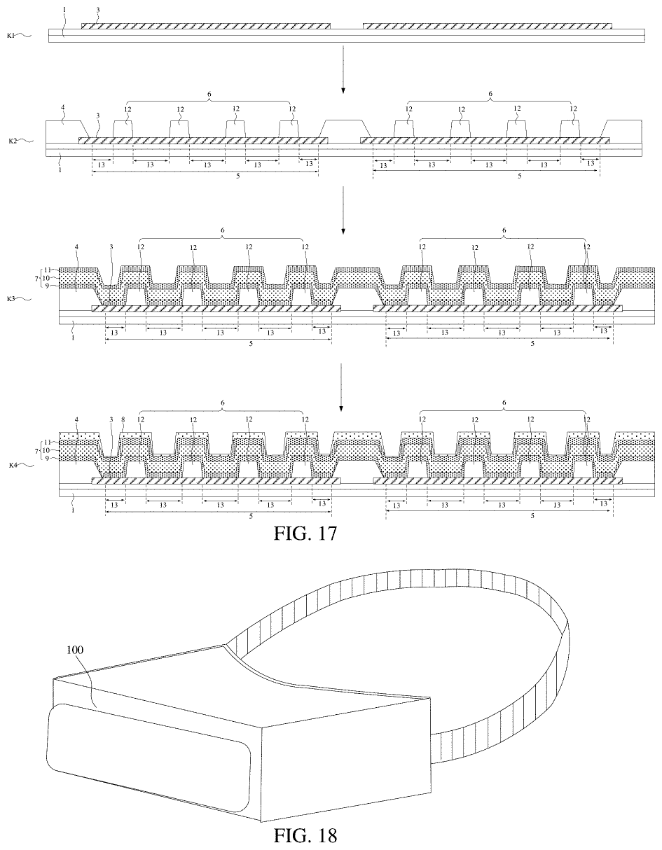

In some embodiments where the fence structures are located on the first electrode as illustrated in FIG. 2, the associated manufacturing process flow is shown in FIG. 17.

In a step K1, a plurality of first electrodes 3 are formed on the substrate 1 by using magnetron sputtering or high-temperature vapor deposition methods, followed by a lithography process. The first electrodes 3 is selected from a group of materials of high work function, such as indium tin oxide (ITO), so that a high injection efficiency of hole carrier from the first electrode can be achieved. In a top-emission type light-emitting device, a part of light emitted from the light-emitting layer 10 towards the substrate 1 can be efficiently reflected back. Alternatively, in some embodiments of top-emission OLED, the first electrodes 3 includes a sandwich structure, such as ITO-Ag-ITO, where the metal between the two ITO layers is selected from a metal material group with high reflectivity.

In a step K2, fence structures 6 and a PDL 4 are formed.

In a step K3, inert gas is introduced into the vapor deposition chamber, and a hole injection and transport layer 9, a light-emitting layer 10, and an electron injection and transport layer 11 are sequentially formed by the vapor deposition.

In a step K4, a gas pressure of the inert gas in the vapor deposition chamber is substantially reduced, and a second electrode 8 is formed by the vapor deposition.

The dimensions of the fence structure 6 and the materials of the fence structure 6, as well as the deposition processes for the multiple layers of the light-emitting elements have been described in aforementioned embodiments and therefore are not repeated herein.

FIG. 18 illustrates a structure of an OLED display device according to an embodiment of the present disclosure, wherein the OLED display device includes the aforementioned OLED display panel. Various structures of the OLED display panel have been described in detail in the aforementioned embodiments, and therefore are not repeated herein. The OLED display device shown in FIG. 18 is a glasses device applied in the field of augmented reality and virtual reality.

It should be noted that, the above-described embodiments are merely for illustrating technical solutions of the present disclosure but not intended to provide any limitations. Although the present disclosure has been described in detail with reference to the above-described embodiments, it should be understood, it is still possible for those skilled in the art that to modify the technical solutions described in the above embodiments or to equivalently replace some or all of the technical features therein, without departing from the essence of corresponding technical solutions of the present disclosure.

What is claimed is:

1. An OLED display panel, comprising:
a substrate, and
a light-emitting device disposed on the substrate, the light-emitting device comprising:
a first electrode;
a pixel definition layer located on a side of the first electrode facing away from the substrate, the pixel definition layer comprising a plurality of openings which expose a part of the first electrode;
fence structures located in the plurality of openings and facing away from the substrate;
a light-emitting functional layer provided on a side of the pixel definition layer, the plurality of openings, and the fence structures, facing away from the substrate; and
a second electrode overlapped on the light-emitting functional layer;
wherein each of the fence structures comprises fences, and trenches which are spaces formed between the fences and the pixel definition layer, and between two adjacent fences; and
the second electrode has a thickness distribution with a thicker layer on a top of each of the fences and a thinner layer on a bottom of the trenches and on a side wall of the fences.

2. The OLED display panel according to claim 1, wherein each of the fence structures comprises a plurality of first fences each of which is ring-shaped, and the plurality of first fences is arranged either in a concentric ring manner or in a matrix in a plane parallel to the substrate.

3. The OLED display panel according to claim 2, wherein the plurality of first fences are substantially equally spaced from each other in the plane parallel to the substrate.

4. The OLED display panel according to claim 2, wherein the dimensions of the plurality of first fences satisfy the equation 0.5≤h/d1≤2, where h is a height of the first fences, d1 is an average thickness of the first fences.

5. The OLED display panel according to claim 2, wherein the dimensions of the plurality of first fences satisfy the equation 0.3≤d1/(d1+d2)≤0.75, where d1 is an average thickness of the plurality of first fences, and d2 is a width of the trench.

6. The OLED display panel according to claim 2, wherein the dimensions of the plurality of first fences satisfy the equation 0.5≤h/d2≤2, where h is a height of the first fences, d2 is a spatial distance between two adjacent first fences of the plurality of first fences.

7. The OLED display panel according to claim 2, wherein an average thickness of the plurality of first fences d1, and a trench width d2 which is measured by a spatial distance between two adjacent first fences of the plurality of first fences, are smaller than or equal to 100 nm.

8. The OLED display panel according to claim 2, wherein each of the fence structures further comprises a second fence, and the second fence connects the plurality of first fences and the pixel definition layer.

9. The OLED display panel according to claim 1, wherein the trenches comprise rectangular or polygonal shaped trenches laid on a plane parallel to the substrate, and inside the openings of the pixel definition layer.

10. The OLED display panel according to claim 1, wherein the fence structures are located between the first electrode and the light-emitting functional layer.

11. The OLED display panel according to claim 1, wherein the fence structures are located between the first electrode and the substrate.

12. The OLED display panel according to claim 10, wherein a height of each of the fences from the substrate is smaller than or equal to a height of the pixel definition layer.

13. The OLED display panel according to claim 1, wherein the fence structures are made of an insulation material.

14. The OLED display panel according to claim 1, wherein the fence structures are made of an electroconductive material.

15. A manufacturing method for forming the OLED display panel according to claim 1, the manufacturing method comprising:
disposing the substrate which is overlaid with the first electrode, the pixel definition layer and the fence structures on a supporting stage inside a vapor deposition chamber;
providing a crucible or a sputtering target containing a raw material for forming the light-emitting functional layer in the vapor deposition chamber, and forming the light-emitting functional layer on the substrate by heating the crucible or plasma bombarding the sputtering target under a first chamber gas pressure; and
providing a crucible or a sputtering target containing a raw material for forming the second electrode in the vapor deposition chamber, and forming the second electrode on the substrate by heating the crucible or plasma bombarding the sputtering target under a second chamber gas pressure,
wherein the first chamber gas pressure is higher than the second chamber gas pressure.

16. The method according to claim 15, wherein said forming the second electrode comprises rotating the supporting stage at a constant speed and in a rotating surface parallel to the substrate.
